(19) United States
(12) Patent Application Publication
(10) Pub. No.: US 2023/0093356 A1
(43) Pub. Date: Mar. 23, 2023

(54) ELECTRONIC DEVICE INSPECTION SOCKET, AND DEVICE AND METHOD FOR MANUFACTURING SAME

(71) Applicant: UNITED PRECISION TECHNOLOGIES CO., LTD., TOKYO (JP)

(72) Inventors: MASARU IENAGA, TOKYO (JP); HIDEKI SATO, TOKYO (JP)

(73) Assignee: UNITED PRECISION TECHNOLOGIES CO., LTD., TOKYO (JP)

(21) Appl. No.: 17/798,090

(22) PCT Filed: Feb. 17, 2021
(86) PCT No.: PCT/JP2021/005892

§ 371 Date: Aug. 8, 2022

(30) Foreign Application Priority Data
Feb. 21, 2020 (JP) JP2020-028509

(51) Int. Cl. H01R 33/76; G01R 1/067

(52) U.S. Cl. CPC H01R 33/76; G01R 1/06705

(57) ABSTRACT

To guarantee positioning of an elastic pin during manufacturing without using a guide member, and to prevent contamination from a guide member in a final product. An electronic device inspection socket having a plurality of elastic pins each having the center portion embedded in, and having respective ends projecting from, an insulator which changes, through solidification, from a fluid state to a solid but deformable state, wherein the leading ends of the elastic pins are portions received by a plurality of recesses provided to a device for manufacturing the electronic device inspection socket, and the insulator is a portion formed after being injected in a fluid state between said respective ends in a state where said respective ends are received in the recesses and being solidified.

### TECHNICAL FIELD

The present invention relates to an electronic device inspection socket, and more particularly to an electronic device inspection socket used for inspection of a semiconductor package (particularly, a semiconductor package for high-frequency applications), a display device (particularly, a liquid crystal display device), and the like.

### BACKGROUND ART

Patent Literature 1 discloses an electrical coupling element for semiconductor element inspection including: a large number of elastic pins that can be elastically compressed in a direction of an external force applied when a semiconductor element is electrically coupled to a tester side and electrically couple a terminal of the semiconductor element to the tester side, the terminal being displaceable; a support member that supports the elastic pin to be elastically compressible; and a guide member that has a guide hole for guiding a position of the terminal of the semiconductor element such that the terminal of the semiconductor element can come into contact with the elastic pin while exposing one side of the elastic pin to the terminal side of the semiconductor element, the guide member being joined to the support member on a side facing the semiconductor element. The elastic pin is provided with at least a middle portion being inserted into the support member. The support member is in contact with the entire outer surface of the middle portion of the elastic pin inserted into the support member. The support member is made of a material having an elastic deformation function and an insulation function.
Patent Literature 1: Korean Patent No. 10-1416266

### SUMMARY OF INVENTION

### Technical Problem

Here, the guide member included in the electrical coupling element for semiconductor element inspection disclosed in Patent Literature 1 functions to position the elastic pins during manufacturing. Therefore, the guide member is a member necessary during manufacturing.

Meanwhile, when the electrical coupling element for semiconductor element inspection is used, the support member is elastically deformed by its elastic deformation function if a force is applied to the elastic pin. At this time, the guide member is also deformed since the support member and the guide member are integrated, and there is a problem in that it is unable to correctly sense the strength of the force applied to the elastic pin.

In order to avoid such trouble, a product of the patentee of Patent Literature 1 was actually purchased to try to peel off the guide member from the support member. However, the guide member was hardly peeled off unless a considerable force is applied since these members were integrated, and further, the elastic pin was deformed or broken at the time of peeling, and thus, such a measure is not acceptable.

Therefore, an object of the present invention is to guarantee positioning of an elastic pin during manufacturing without using a guide member, different from Patent Literature 1, and to prevent a final product from including a guide member.

### Solution to Problem

In order to achieve the above object, the present invention provides an electronic device inspection socket having a plurality of elastic pins each having the center portion embedded in, and having respective ends projecting from, an insulator which changes, through solidification, from a fluid state to a solid but deformable state,

wherein the leading ends of the elastic pins are portions received by a plurality of recesses provided to a device for manufacturing the electronic device inspection socket, and

the insulator is a portion formed after being injected in a fluid state between said respective ends in a state where said respective ends are received in the recesses and being solidified.

Note that the insulator may be made of a silicone resin including silicone rubber, but is not limited thereto.

In addition, each of the elastic pins can be made of, for example, gold, platinum, copper, silver, a copper alloy, or a copper-silver alloy.

In addition, the present invention provides a device for manufacturing an electronic device inspection socket having a plurality of elastic pins each having a center portion embedded in, and having respective ends projecting from, an insulator which changes, through solidification, from a fluid state to a solid but deformable state, the device including:

a first plate in which a plurality of recesses configured to receive leading ends of first ends of the plurality of elastic pins are formed;

a second plate which is arranged opposite to the first plate and in which a plurality of recesses configured to receive leading ends of second ends of the plurality of elastic pins are formed;

a movement unit which relatively moves a distance between the first plate and the second plate; and

an injection unit that injects the insulator in a fluid state between the first plate and the second plate.

Further, the present invention provides a method for manufacturing an electronic device inspection socket having a plurality of elastic pins each having a center portion embedded in, and having respective ends projecting from, an insulator which changes, through solidification, from a fluid state to a solid but deformable state, the method including:

a step of receiving leading ends of the elastic pins in a plurality of recesses provided to a device for manufacturing an electronic device inspection socket;

a step of injecting the insulator in a fluid state between the respective ends in a state where the respective ends are received by the recesses; and a step of removing the leading ends from the device for manufacturing an electronic device inspection socket after the insulator is solidified.

### DESCRIPTION OF EMBODIMENTS

Hereinafter, an electronic device inspection socket 300 according to an embodiment of the present invention will be described with reference to the drawings. Note that the electronic device inspection socket 300 is suitable for inspecting semiconductor packages for high-frequency applications, but is not limited thereto.

FIG. 1 is a schematic configuration view of the electronic device inspection socket 300 according to the embodiment of the present invention. FIG. 1A illustrates a perspective view of electronic device inspection socket 300. FIG. 1B illustrates a cross-sectional view of a part taken along a-a′ of FIG. 1A.

As illustrated in FIGS. 1A and 1B, the electronic device inspection socket 300 includes a plurality of elastic pins 100 having conductivity and a support member 200 which is an insulator supporting the elastic pins 100.

The support member 200 is the insulator that changes from a fluid state to a solid but deformable state through solidification. As a material of the support member 200, for example, a silicone resin including silicone rubber can be adopted.

The hardness of the support member 200 is determined according to applications of the electronic device inspection socket 300. For example, in a case where the electronic device inspection socket 300 is used for inspection of a semiconductor package, a force of 5 gf to 10 gf is often applied to the elastic pin 100, and thus, it is necessary to set the hardness to be relatively low such that the application of the force of such strength can be detected.

On the other hand, for example, in a case where the electronic device inspection socket 300 is used for inspection of a liquid crystal display device, a force of 20 gf to 200 gf is often applied to the elastic pin 100, and thus, it is necessary to set the hardness to be relatively high such that the application of the force of such strength can be detected.

As illustrated in FIG. 1B, a center portion 110 of each of the elastic pins 100 is embedded in the support member 200. In addition, leading ends of ends 120 and 130 of each of the elastic pins 100 project from the support member 200. The projecting amount can be determined according to applications of the electronic device inspection socket 300, but can be set to approximately 1/10 to 1/1 of the height of each of the ends 120 and 130.

FIG. 2 is a schematic view of the elastic pin 100 illustrated in FIG. 1. FIG. 2A illustrates a front view of the elastic pin 100. FIG. 2B illustrates a side view of FIG. 2A.

As illustrated in FIG. 2A, the elastic pin 100 has a continuous S-shape. However, the number of curved portions constituting the S-shape is not limited to that illustrated in FIG. 2A, and may be larger or smaller than the illustrated number. Therefore, the shape of the elastic pin 100 is not limited to the S-shape, and may be, for example, a C-shape having one curved portion.

Although described with reference to FIG. 1, the elastic pin 100 includes the center portion 110 formed of an S-shaped portion and the ends 120 and 130 having substantially rectangular shapes and located at both ends of the center portion 110.

As illustrated in FIG. 2B, the elastic pin 100 has a planar shape. However, the shape of the elastic pin 100 is not limited to the planar shape, and may be, for example, a spiral shape.

The elastic pin 100 may be made of a material, for example, pure gold, pure platinum, pure copper, and pure silver in which impurities and the like are not substantially mixed, a copper alloy in which another material is mixed with copper, a copper-silver alloy in which a predetermined amount of copper and a predetermined amount of silver are mixed, or the like, but is not limited thereto. A method for manufacturing the elastic pin 100 using the copper-silver alloy as the material will be described later.

A size of each portion of the elastic pin 100 can be set as follows as an example, but is not limited thereto.

Ends 120 and 130: About 0.20 mm to 0.50 mm in width, About 0.10 mm to 0.30 mm in height,

Center portion 110: About 0.20 mm to 0.50 mm in width, About 0.20 mm to 0.60 mm in height, About 0.015 mm to 0.10 mm in width in the S-shaped portion,

Total thickness of Elastic pin 100: about 0.03 mm to 0.20 mm

When the center portion 110 is configured in this manner as illustrated in FIG. 2A, the center portion 110 can be deformed by a load applied to the elastic pin 100 through the ends 120 and 130.

Next, the method for manufacturing the elastic pin 100 in the case of using the copper-silver alloy as the material will be described. First, for example, electric copper or oxygen-free copper which is a commercially available product and shaped into a strip shape of 10 mm×30 mm×50 mm is prepared. Then, granular silver having a general shape with a primary diameter of about 2 mm to 3 mm is prepared.

Thereafter, an additive amount of the silver to the copper is in a range of 0.5 wt % to 15 wt %, more preferably in a range of 2 wt % to 10 wt %. Then, the copper added with the silver is placed into a melting furnace, such as a high-frequency or low-frequency vacuum melting furnace including a Tamman furnace, the melting furnace is turned on to raise a temperature to, for example, about 1200° C., and the copper and the silver are sufficiently melted to perform casting. In this manner, a copper-silver alloy ingot is manufactured.

Thereafter, the copper-silver alloy ingot is subjected to a solutionizing heat treatment. At this time, the copper-silver alloy can be also cast in the atmosphere, and can also be cast in an inert atmosphere such as a nitrogen gas or an argon gas. In the former case, the surface of the copper-silver alloy ingot is oxidized, and thus, such an oxidized portion is ground. On the other hand, in the latter case, a surface grinding treatment of the copper-silver alloy ingot is unnecessary.

After the copper-silver alloy is subjected to the solutionizing heat treatment, cold rolling is performed, and a precipitation heat treatment is performed at, for example, 350° C. to 550° C. Next, as is known, a photosensitive substance, such as silver iodide, silver bromide, or acrylic, is applied to a surface of a copper-silver alloy plate, cut out to correspond to a thickness of the elastic pin 100 from a copper-silver alloy body after having been subjected to the precipitation heat treatment, by spraying, impregnation, or the like.

At this time, if necessary, a coupling agent may be applied to the copper-silver alloy body to enhance adhesion of the photosensitive substance before the application of the photosensitive substance. In addition, the photosensitive substance may be solidified by performing a pre-bake treatment in which the copper-silver alloy body coated with the photosensitive substance is heated at a temperature of about 100° C. to 400° C. for a predetermined time.

Next, a mask pattern having a shape corresponding to the shape of the elastic pin 100 is formed on the copper-silver alloy plate. A method for forming the mask pattern is not particularly limited, and any known plating method, such as electrolytic plating, electroless plating, hot dipping, or vacuum deposition, may be adopted.

A metal film formed by the plating may have a thickness of about 0.50 μm to 5.00 μm, and nickel, chromium, copper, aluminum, or the like can be used as a material thereof. Note that the mask pattern may be either a positive type or a negative type.

Subsequently, the copper-silver alloy plate is exposed to light by an exposure device (not illustrated). It suffices that the exposure device is capable of emitting ultraviolet light with a wavelength of about 360 nm to 440 nm (for example, 390 nm) and an output of about 150 W. Specifically, the exposure device can be configured using a xenon lamp, a high-pressure mercury lamp, or the like, but is not limited thereto.

Only one exposure device may be provided, or a plurality of exposure devices may be provided. In the latter case, the exposure time can be shortened. Note that it suffices that a distance between the exposure device and the copper-silver alloy plate is about 20 cm to 50 cm as long as the above-described irradiation condition of ultraviolet light is satisfied.

Subsequently, the copper-silver alloy plate is placed into a developer in order to remove an unnecessary photosensitive material from the copper-silver alloy plate having been subjected to the exposure treatment using the exposure device. It suffices that the developer is selected in accordance with the photosensitive material, and a 2.38 wt % aqueous solution of tetra-methyl-ammonium-hydroxide (TMAH), which is an organic alkali, can be used.

Thereafter, a desired rinse treatment is performed, and then, an etching treatment is performed with an etching solution suitable for etching a copper alloy, such as ferric chloride having a specific gravity of about 1.2 to 1.8 or a mixed solution of ammonia persulfate and mercuric chloride. Note that it is also possible to selectively add a small amount (for example, about 5%) of an etching solution suitable for etching silver, such as a ferric nitrate solution having a similar specific gravity.

Consequently, even if a silver lump or the like is generated at the time of melting, the silver lump can be prevented from remaining on the surface of the copper-silver alloy body after the etching treatment. However, if an additive amount of the ferric nitrate solution or the like is large, a ratio of silver on the surface of the copper-silver alloy plate after the etching treatment decreases, and surface strength of the elastic pin 100 decreases, which is not preferable.

It suffices that the time for impregnating the copper-silver alloy plate in the etching solution may be determined in accordance with the material, thickness, and the like of the copper-silver alloy plate, but is generally set to 2 minutes to 15 minutes, for example, to 10 minutes or less. Through the above steps, the elastic pin 100 having a desired shape can be manufactured from the copper-silver alloy plate.

Note that, if the surface of the elastic pin 100 is coated with carbon such as graphene, nano-silver, or the like by electroplating, vacuum deposition, electrostatic spraying, or the like to have a thickness of about 2 μm to 3 μm, the conductivity can be further improved, and an allowable current of the elastic pin 100 can be improved.

FIG. 3 is an explanatory view of a manufacturing device 400 of the electronic device inspection socket 300 illustrated in FIG. 1. FIG. 3 illustrates a first plate 420 in which a plurality of recesses 410 configured to receive the leading ends of the ends 130 of the plurality of elastic pins 100 are formed; a second plate 440 in which a plurality of recesses 430 configured to receive the leading ends of the ends 120 of the plurality of elastic pins 100 are formed; a movement unit 450 that relatively moves the first plate 420 and the second plate 440 in the vertical direction of the drawing; and an injection unit 460 having one or a plurality of nozzles 470 configured to inject, between the first plate 420 and the second plate 440, a silicone resin or the like (thermoplastic resin), such as silicone rubber, in a fluid state as a precursor of the support member 200.

Note that FIG. 3 illustrates a cross section of the manufacturing device 400, and peripheral edges of the first plate 420 and the second plate 440 are formed with peripheral edge portions defining an outer edge of the electronic device inspection socket 300.

That is, a region into which the silicone resin is injected is a region surrounded by a bottom surface of the first plate 420, an upper surface of the second plate 440, and the peripheral edge portions thereof. Strictly speaking, a first opening corresponding to the nozzle 470 of the injection unit 460 is formed in the peripheral edge portions. In addition, a second opening configured to discharge air in the region at the time of injecting the silicone resin is formed in the peripheral edge portions on a side opposite to a side where the injection unit 460 is located or from a bottom surface to the upper surface of the second plate 440.

Each of the recesses 410 and each of the recesses 430 have sizes and shapes corresponding to the leading ends of the end 130 and the end 120, respectively. Therefore, the elastic pins 100 are positioned in a state where the leading ends of the ends 130 and the ends 120 are accommodated in the recesses 410 and the recesses 430.

Note that, for example, it is also possible to adopt a configuration in which opening ends are located on bottom surfaces of the respective recesses 410, a cavity portion in which the opening ends communicate with each other is provided, and a pressure-reducing pump is connected to the cavity portion.

Consequently, when the pressure-reducing pump is turned on after the leading ends of the ends 130 are accommodated in the recesses 410, respectively, it is possible to avoid separation of the leading end of each of the ends 130 from each of the recesses 410 and positional displacement in each of the recesses 410. It should be noted that it is unnecessary to perform relatively strong suction as in a vacuum pump since it suffices that the pressure-reducing pump can avoid the separation and the like.

Just to be sure, the cavity portion in this case has a form that includes a first end being connected to the pressure-reducing pump, base ends that branch as many as the number of the recesses 410, and second ends serving as the above-described opening ends to be connected to the bottom surfaces of the respective recesses 410. A similar configuration may be adopted for the recesses 430 side.

Specifically, a method for manufacturing the electronic device inspection socket 300 will be described. First, the leading ends of the ends 130 of the plurality of elastic pins 100 are accommodated in the plurality of recesses 410 formed in the first plate 420.

Thereafter, the movement unit 450 to which the second plate 440 is attached is lowered such that the leading ends of the ends 120 of the plurality of elastic pins 100 are accommodated in the plurality of recesses 430 formed in the second plate 440.

In this manner, the elastic pins 100 are fixed by the first plate 420 and the second plate 440. Note that, in a case where the manufacturing device 400 is of a type including the cavity portion described above, it suffices that the pressure-reducing pump is turned on before injecting a silicone resin in a fluid state which is a precursor of the support member 200 to be described below.

Thereafter, the silicone resin in the fluid state, which is the precursor of the support member 200, is injected by the injection unit 460 between the first plate 420 and the second plate 440, that is, between both the ends 120 and 130 of each of the elastic pins 100.

Note that the silicone resin in the fluid state is injected along a plane direction of each of the elastic pins 100 as illustrated in FIG. 3. In this manner, the silicone resin is prevented from flowing around a gap between the elastic pins 100 to avoid generation of a rim portion.

In addition, FIG. 3 illustrates the manufacturing device 400 intended to manufacture one electronic device inspection socket 300, but the manufacturing device 400 that can manufacture a plurality of the electronic device inspection sockets 300 may be configured.

Thereafter, when the silicone resin is solidified, the electronic device inspection socket 300 is completed. The pressure-reducing pump is turned off in the case of being used, and then, the movement unit 450 is raised. Then, the completed electronic device inspection socket 300 is removed from the first plate 420.

As described above, it is possible to manufacture the electronic device inspection socket 300 without using a guide member that causes trouble at the time of inspection according to each embodiment of the present invention.

### BRIEF DESCRIPTION OF DRAWINGS

FIG. 1 is a perspective view and a cross-sectional view of an electronic device inspection socket 300 according to an embodiment of the present invention.

FIG. 2 is a front view and a side view of an elastic pin 100 illustrated in FIG. 1.

FIG. 3 is an explanatory view of a manufacturing device 400 of the electronic device inspection socket 300 illustrated in FIG. 1.

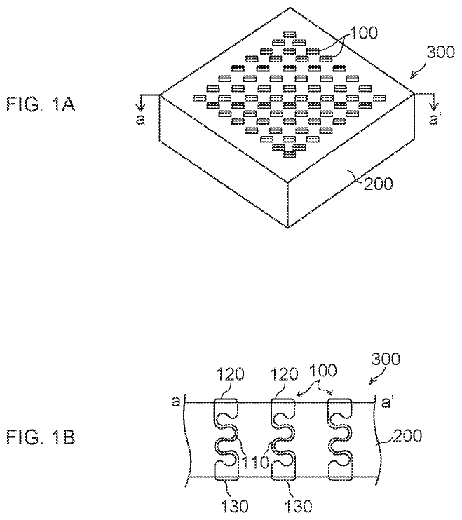

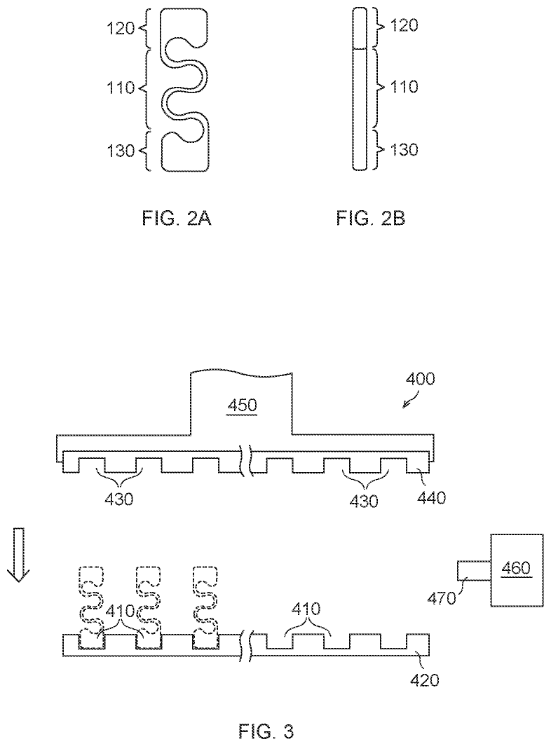

### REFERENCE SIGNS LIST

100 elastic pin
110 center portion
120, 130 end
200 support member
300 electronic device inspection socket
400 manufacturing device
410, 430 recess
420 first plate
440 second plate
450 movement unit
460 injection unit
470 nozzle

1. An electronic device inspection socket comprising:
an insulator which changes, through solidification, from a fluid state to a solid but deformable state; and a plurality of elastic pins each having a center portion embedded in the insulator and having respective ends projecting from the insulator,
wherein leading ends of the elastic pins are portions received by a plurality of recesses provided to a device for manufacturing the electronic device inspection socket, and
the insulator is a portion solidified after being injected in a fluid state between the respective ends in a state where the respective ends are received in the recesses.

2. The electronic device inspection socket according to claim 1, wherein the insulator is a thermosetting resin.

3. The electronic device inspection socket according to claim 1, wherein each of the elastic pins is made of gold, platinum, copper, silver, a copper alloy, or a copper-silver alloy.

4. A device for manufacturing an electronic device inspection socket having a plurality of elastic pins each having a center portion embedded in, and having respective ends projecting from, an insulator which changes, through solidification, from a fluid state to a solid but deformable state, the device comprising:
a first plate in which a plurality of recesses configured to receive leading ends of first ends of the plurality of elastic pins are formed;
a second plate which is arranged opposite to the first plate and in which a plurality of recesses configured to receive leading ends of second ends of the plurality of elastic pins are formed;
a movement unit which relatively moves a distance between the first plate and the second plate; and
an injection unit that injects the insulator in a fluid state between the first plate and the second plate.

5. A method for manufacturing an electronic device inspection socket having a plurality of elastic pins each having a center portion embedded in, and having respective ends projecting from, an insulator which changes, through solidification, from a fluid state to a solid but deformable state, the method comprising:
a step of receiving leading ends of the elastic pins in a plurality of recesses provided to a device for manufacturing an electronic device inspection socket;
a step of injecting the insulator in a fluid state between the respective ends in a state where the respective ends are received by the recesses; and
a step of removing the leading ends from the device for manufacturing an electronic device inspection socket after the insulator is solidified.
